(19) United States
(12) Patent Application Publication
(10) Pub. No.: US 2008/0265375 A1
(43) Pub. Date: Oct. 30, 2008

(54) Methods for the single-sided polishing of semiconductor wafers and semiconductor wafer having a relaxed Si1-x GEx Layer

(75) Inventors: Georg Pietsch, Burghausen (DE); Thomas Buschhardt, Burghausen (DE); Juergen Schwandner, Garching (DE)

Correspondence Address: BROOKS KUSHMAN P.C., 1000 TOWN CENTER, TWENTY-SECOND FLOOR, SOUTHFIELD, MI, 48075, US

(73) Assignee: Siltronic AG, Munich (DE)

(21) Appl. No.: 12/148,739

(22) Filed: Apr. 22, 2008

(30) Foreign Application Priority Data
Apr. 27, 2007 (DE) 2007 019 565.8

(51) Int. Cl. H01L 21/306; H01L 29/30

(52) U.S. Cl. 257/616; 438/693; 257/E29.106; 257/E21.23

(57) ABSTRACT

Single-sided polishing of semiconductor wafers provided with a relaxed Si₁₋ₓGeₓ layer involves polishing of a multiplicity of wafers in a plurality of polishing runs, a polishing run having at least one polishing step, at least one of the multiplicity of wafers obtained with a polished Si₁₋ₓGeₓ layer at the end of each polishing run; moving the wafer during the polishing step over a rotating polishing plate provided with a polishing cloth while applying polishing pressure, and supplying polishing agent between the polishing cloth and the semiconductor wafer, the polishing agent containing an alkaline component and a component that dissolves germanium. Semiconductor wafer having a Si₁₋ₓGeₓ layer substantially free of defects and haze is produced.

This application claims priority to German Application No. 10 2007 019565.8 filed Apr. 24, 2007.

### BACKGROUND OF THE INVENTION

1. Field of the Invention

The invention relates to a method for the single-sided polishing of semiconductor wafers which are provided with a relaxed Si₁₋ₓGeₓ layer. The invention also relates to a semiconductor wafer having such a layer.

2. Background Art

Modern applications in microelectronics, for example information and communication technology, require ever-higher integration densities and ever-shorter response times and clock rates of the microelectronic components on which they are based. Components are, for example, memory cells, switching and control elements, transistors, logic gates and the like. These are produced from substrates made of semiconductor materials. Semiconductor materials comprise elementary semiconductors such as silicon and occasionally also germanium, or compound semiconductors, for example gallium arsenide (GaAs). One measure of the switching speed is the mobility of the charge carriers (free electrons, holes). The mobility is the average drift velocity of the charge carriers in the crystal lattice of the semiconductor material, in relation to the applied electric field (electrical voltage per distance unit). The electron mobility for pure silicon is substantially lower than, for example, GaAs. Nevertheless, silicon is the standard material of microelectronics for numerous reasons. Silicon is expediently, readily and virtually unlimitedly available, nontoxic, very clean to produce, can be processed very well and with a high absence of impurities, and has a stable oxide (dielectric). There is therefore a desire to be able to produce particularly rapid components on the basis of silicon technology.

For a given material, it is possible to increase the charge-carrier mobility only by artificial modification of the properties of the crystal lattice. From theoretical studies, it is known that in particular, straining of the crystal lattice (extension, distortion) increases the mobility. The average atomic spacing (lattice constant) of germanium, which is homologous to silicon, is about 4% greater than that of silicon. A silicon crystal with incorporated germanium atoms therefore has a larger lattice constant than pure silicon. In order to achieve this, a silicon layer with a germanium component increasing gradually with the layer thickness is deposited on a defect-free, plane and pure silicon starting surface. This is done from the gas phase by means of thermolysis (chemical vapor deposition, CVD) of gaseous precursors containing germanium, for example GeH₄, GeCl₄, GeHCl₃, on the surface or by evaporation coating with particle beams (molecular beam epitaxy, MBE). Owing to this gradient layer with a varying Si/Ge stoichiometry, the strain built up in the crystal because of the lattice mismatch of silicon and germanium is kept small during growth. A further relaxation is achieved by subsequent deposition of a stoichiometrically constant buffer layer having the germanium content of the last level of the Si₁₋ₓGeₓ gradient layer. The overall layer structure is referred to as a strain-relaxed layer.

If pure silicon is deposited in a small layer thickness on the relaxed layer, then the layer imposes its atomic spacing on the silicon atoms. The deposited silicon layer is laterally stretched and is therefore referred to as a strained silicon lattice. Components structured in such a strained silicon layer have a charge-carrier mobility which is increased according to the degree of strain and therefore the germanium component of the relaxed layer.

A prerequisite for the functional integrity of components with short switching and charge-carrier transport times is substantial freedom of the strained silicon layer from defects. It has been found that part of the strain of the Si₁₋ₓGeₓ gradient layer due to the lattice mismatch relaxes in the form of regularly occurring lattice defects. These form a network of so-called dislocation defects (screw dislocations) at the points of intersection with the growth surface. This defect network leads to regular height modulations of the surface. On the preferred Si (100) substrate, these faults resemble diamond-shaped shading of the surface, and are therefore referred to as a “cross-hatch defect pattern”.

U.S. Pat. No. 6,475,072 and Sawano et al., Materials Science and Engineering B89 (2002) 406-409 describe polishing methods which are intended to smooth Si₁₋ₓGeₓ layers. The methods involve chemical-mechanical polishing (CMP) in which the semiconductor wafer is moved over a rotating polishing plate provided with a polishing cloth while applying polishing pressure, and at the same time supplying a polishing agent between the polishing cloth and the Si₁₋ₓGeₓ layer to be polished. The remaining roughness, measured by AFM (atomic force microscopy), is in the best case 5 Å RMS (root mean square) in relation to a measurement grid with an area of 10 μm×10 μm.

A surface polished in this way, however, comprises perturbing craters which are also often referred to as “nanocraters” owing to their typical widths and depths in the sub-micrometer range. FIG. 1 shows an AFM image of a relaxed Si₁₋ₓGeₓ layer polished according to the prior art, on which a large number of nanocraters may be seen. Yet even when few nanocraters or no nanocraters are to be seen on an AMF image, scattered light measurements at longer “spatial wavelengths” show comparatively a high micro-roughness of the surface and the presence of individual light point defects.

Scattered light measurements are standard methods for describing the surface quality. A collimated light beam (laser light) grazes the surface. Roughness or variations in the dielectric constant, for example due to coatings or extraneous material particles on the surface, cause part of the incident light intensity to be scattered away from the specularly reflected beam whenever the detected irregularities have a size in the range of the wavelength of the light being used or are correlated in this range. The scattered light intensity component, substantially scattered uniformly into the dark field, is referred to as “haze”, and is measured in fractions of the incident light intensity. It describes the microroughness of the surface. The locally varying proportion of intensity scattered into the dark field identifies individual “light point defects” (LPDs), and is specified in units of the characteristic scattered light intensity of particles with a known size (LSE, “light scattering equivalent”).

FIG. 2 and FIG. 3 shows the result of scattered light measurements on a relaxed Si_{0.8}Ge_{0.2} layer polished according to the prior art. FIG. 2 shows the distribution of all LPD defects 2 measured in the DNN channel with LSE sizes≧0.13 μm. The names of the channels refer to the size of the acceptance angle in the dark field around the specularly reflected measurement beam and the incidence angle of the measurement beam on the semiconductor wafer: DNN means “dark field, narrow acceptance, normal incidence beam”, DWN means “dark field, wide acceptance, normal incidence beam” and DCN means “dark field, composite acceptance, normal incidence beam”. The DCN channel is the channel made up of the LPD defects registered in the DNN channel, in the DWN channel and as so-called “area defects”; LPD defects which have been registered in several of the individual channels are counted only once. DNN, DWN and DCN respectively evaluate the LPD defects according to LSE size classes. In the DCN channel in the example given in FIG. 2, 37 LPD defects were measured for scattering equivalent sizes of 0.13 μm-0.16 μm, 16 were measured for 0.16 μm-0.20 μm and 1 defect was measured for 0.20 μm-0.24 μm. LPD defects with LSE sizes of more than 0.24 μm are categorised as area defects. In the example shown, 7 area defects were registered. The example shown therefore gives in total 37+16+1+7=61 LPD defects for LSE sizes≧0.13 μm in the DCN channel.

FIG. 3 gives the frequency C (in percent) of the scattered light intensities I measured over the semiconductor wafer in the DNN channel (as ppm of the incident beam intensity; ppm=part per million, 10⁻⁶). This scattered light is referred to as “DNN haze”. The haze is a measure of the microroughness of the surface of the semiconductor wafer. For the example shown in FIG. 3, the DNN haze integrated over all intensities and weighted with the frequency determined for the intensities is 0.221 ppm.

The high roughness of a relaxed Si₁₋ₓGeₓ layer polished according to the prior art is manifested in a characteristic inhomogeneous profile of the haze spectrum shown in FIG. 3, having a non-monotonic frequency decrease with increasing scattered light intensity (multimodal distribution with peaks 3 and 4).

Si₁₋ₓGeₓ layers planarized according to known methods are therefore still too rough in order for a strained silicon layer, which is sufficiently low in defects, smooth and plane for particularly demanding applications, to be deposited on them.

### SUMMARY OF THE INVENTION

It is therefore an object of the present invention to provide a method for polishing relaxed Si₁₋ₓGeₓ layers, which provides a surface suitable for the growth of a low-defect, smooth and plane strained silicon layer so that the strained silicon layer is suitable for the structuring of particularly demanding high-speed microelectronic components. These and other objects are achieved by a method for the single-sided polishing of semiconductor wafers which are provided with a relaxed Si₁₋ₓGeₓ layer, comprising polishing a multiplicity of semiconductor wafers in a plurality of polishing runs, a polishing run comprising at least one polishing step and at least one of the multiplicity of semiconductor wafers being obtained with a polished Si₁₋ₓGeₓ layer at the end of each polishing run; and moving the at least one semiconductor wafer during the at least one polishing step over a rotating polishing plate provided with a polishing cloth while applying polishing pressure, and supplying polishing agent between the polishing cloth and the at least one semiconductor wafer, a polishing agent being supplied which contains an alkaline component and a component that dissolves germanium.

### BRIEF DESCRIPTION OF THE DRAWINGS

FIG. 1 is an AFM image of a relaxed Si₁₋ₓGeₓ layer polished by the prior art polishing method;

FIG. 2 shows the distribution of LPD defects in the DNN channel of a prior art polished wafer;

FIG. 3 gives the frequency of scattered light intensities measured in the DNN channel for a prior art polished wafer;

FIG. 4 illustrates the effects of the presence or absence of oxidant in the CMP slurry for polishing wafers with an Si₁₋ₓGeₓ relaxed layer;

FIG. 5 illustrates the effects of H₂O₂ as an oxidant in the CMP slurry;

FIG. 6 illustrates schematically one possible polishing apparatus suitable for use in the present invention;

FIG. 7 illustrates one possible geometric path of a wafer to be polished;

FIG. 8 illustrates a second possible geometric path of a wafer to be polished;

FIGS. 9 and 10 show results of scattered light measurements of a wafer polished in accordance with the subject invention;

FIG. 11 shows LPD defects of wafers polished in accordance with the method of the invention in the DCN channel;

FIG. 12 shows Chapman roughness of wafers polished in accordance with the method of the invention;

FIG. 13 shows AFM measurements of the wafer surface of a wafer polished by the method of the invention; and

FIG. 14 shows an AFM image of a relaxed Si_{0.8}Ge_{0.2} layer which was polished according to the invention.

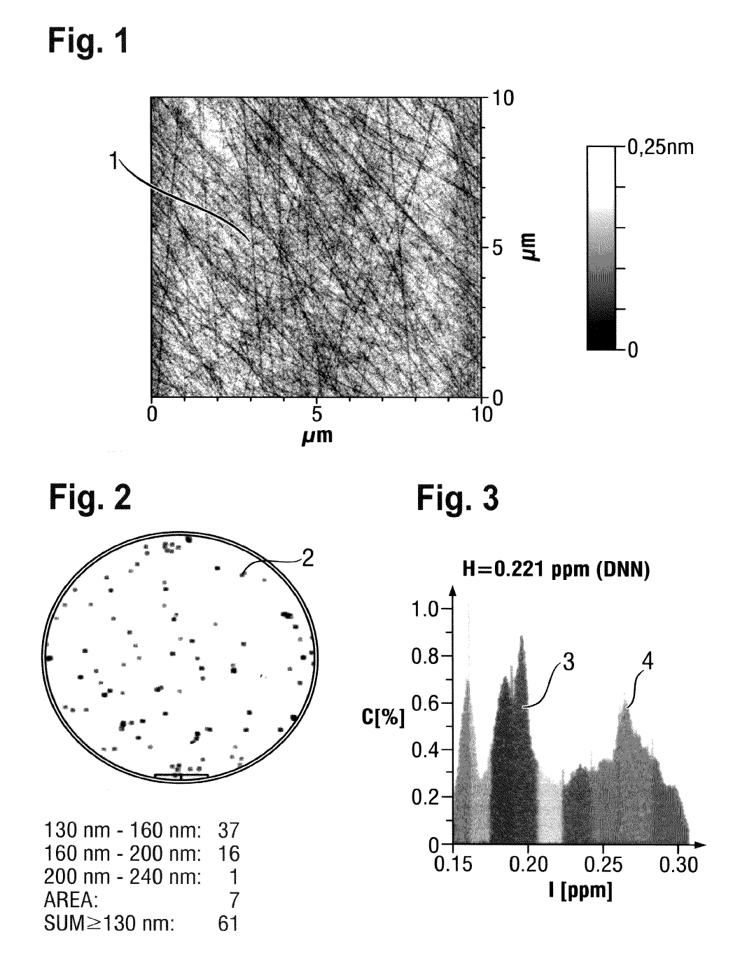

### DETAILED DESCRIPTION OF THE PREFERRED EMBODIMENT(S)

It is now believed that particles which contain germanium and are left behind when silicon is dissolved under the conditions of chemical-mechanical polishing, are the cause of the comparatively high roughness and the nanocraters after polishing. Surprisingly, it is not sufficient to remove these particles mechanically, for example in the course of treating the polishing cloth. Rather, it is necessary to at least begin to dissolve these particles chemically even during polishing. This is preferably achieved in that the polishing agent contains an oxidant which converts germanium into a water-soluble oxide compound, as one of its components. Hydrogen peroxide (H₂O₂), ozone (O₃), sodium hypochlorite (NaOCl), sodium perchlorate (NaClO₄), sodium chlorate (NaClO₃) and other oxidants are particularly suitable. Mixtures of at least two of these oxidants are also feasible. The oxidant is preferably supplied in the form of an aqueous solution to the polishing agent.

Besides the component that dissolves germanium, the polishing agent also contains an alkaline component, preferably potassium carbonate (K₂CO₃), potassium hydroxide (KOH), sodium hydroxide (NaOH), ammonium hydroxide (NH₄OH), or tetramethylammonium hydroxide (N(CH₃)₄OH), or any mixture of these substances, more preferably a mixture of potassium carbonate and potassium hydroxide or tetramethylammonium hydroxide. The concentration of the alkaline component in the polishing agent will be selected so that the polishing agent preferably has a pH of from 9 to 11.5. The germanium-dissolving component in the polishing agent will preferably be supplied to the semiconductor wafer only as close as possible to the “point of use” of the polishing agent, since oxidants are generally unstable and their concentration therefore decreases, particularly owing to interaction with impurities in the polishing agent. As an alternative, oxidants may be added to a polishing agent batch in an initially higher concentration and the “shelf life” of the polishing agent may be restricted so that precisely the desired concentration is available at the point where the polishing agent interacts with the semiconductor wafer.

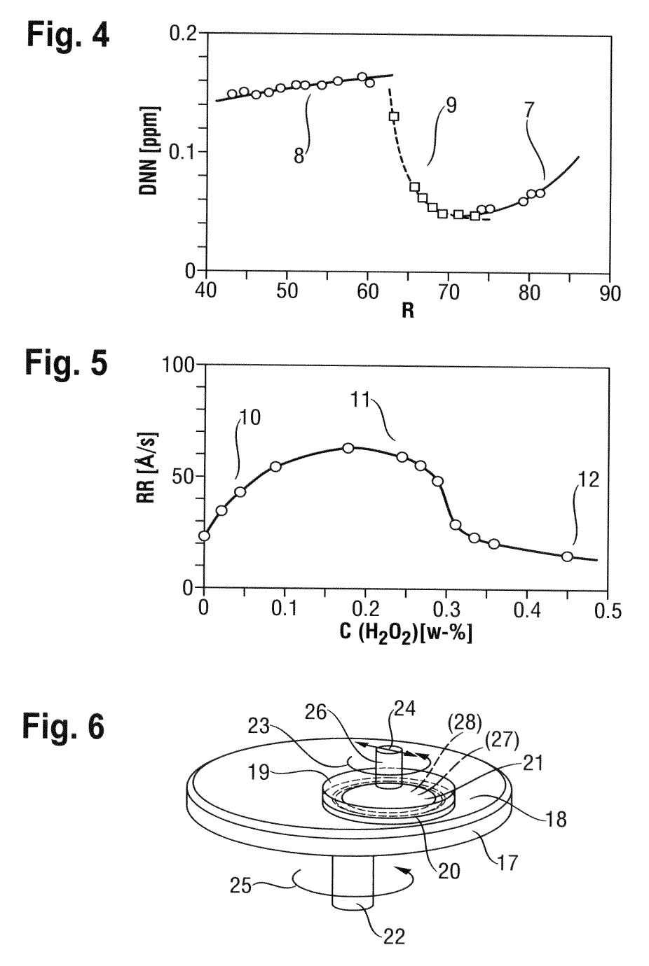

FIG. 4 shows the result of a study in which the conditions relating to supply the oxidant were varied over a plurality of polishing “runs” (R). During a first phase 8, the supplied polishing agent contained no germanium-dissolving component and the cloth was cleaned after each run. Scattered light measurements on the polished surface show a level of “haze” which is high from the start and increases in the course of phase 8.

A possible explanation for the increase in the roughness is that the germanium particles accumulate in the polishing cloth over time and increasingly leave behind nanocraters on subsequently polished semiconductor wafers. The roughness of the polished surfaces decreases significantly when, as during phase 9, the polishing agent additionally contains an oxidant such as hydrogen peroxide, and it increases again when the oxygen is omitted, as during phase 7.

The concentration of the oxidant in the polishing agent is preferably from 0.01 mol/kg to 1.0 mol/kg, in particular from 0.01 to 0.20 mol/kg, most preferably from 0.06 to 0.12 mol/kg. It is also preferable for the concentration of the oxidant to be matched to the concentration of the germanium component of the relaxed Si₁₋ₓGeₓ layer. The higher the germanium component is, e.g. 70%, the higher the concentration of the oxidant should be. It should however not be too high, so that the removal rate (RR) of the polishing does not become too low. In a polishing step configured as a material removal step, the removal rate is preferably at least 1.5 nm/s, more preferably 2 nm/s. The removal rate decreases commensurately as silicon is oxidized to silicon dioxide, which resists the polishing more strongly. The optimal concentration of the oxidant may best be determined by experiments in which the concentration of the oxidant is varied and is compared with the polishing result obtained. FIG. 5 summarizes the result of a corresponding study for Si_{0.8}Ge_{0.2} layers and for hydrogen peroxide as the oxidant. In FIG. 5, 10 denotes a region in which a low removal rate is obtained owing to a low concentration of the germanium-dissolving additive (oxidant). 12 denotes a region in which the equilibrium between the germanium-dissolving component and the alkaline component, which attacks silicon, is shifted in favor of the germanium-dissolving component, which likewise causes a low removal rate. 11 denotes a region in which high polishing removal is achieved owing to a balanced ratio of the alkaline component and the germanium-dissolving component in the polishing agent. Accordingly, the removal rate of the polishing has its maximum when the H₂O₂ concentration in the polishing agent lies in a particularly preferred range of from 0.1 to 0.3 wt. %.

It is also advantageous, and therefore likewise preferred, to treat the polishing cloth, this being intended to mean mechanical or hydrodynamic processing of the polishing cloth while simultaneously supplying a germanium-dissolving cleaning agent to the polishing cloth. Suitable treatment tools are for example brushes, preferably with bristles made of polyimide, or treatment heads covered with hard substances such as diamond or silicon carbide, or nozzles by which a water jet, to which ultrasound is optionally applied, is directed at a high pressure onto the polishing cloth. The cleaning agent preferably has a pH of from 9 to 11.5 and expediently, but not necessarily, contains the same oxidant as the polishing agent. The polishing cloth may be treated during or after a polishing step, or after a particular number of polishing runs; these treatment times also being able to be combined arbitrarily with one another. If the treatment takes place during a polishing step, i.e. in the presence of the semiconductor wafer to be polished, then it is preferable for the oxidant concentration in the cleaning agent to lie in the range of the concentration of the oxidant in the polishing agent. If the polishing cloth is treated in the absence of the semiconductor wafer, then it is preferable for the cleaning agent to contain the oxidant in a concentration of from 0.01 mol/kg to 1.5 mol/kg. In this case, it is favorable to wash the polishing cloth with water before beginning a further polishing step. The frequency at which the polishing cloth is treated may also be increased with the number of polishing runs completed, in order to prevent germanium particles from accumulating in the polishing cloth over time.

The polishing agent used according to the invention preferably has further properties, which lead to a particularly smooth polished relaxed Si₁₋ₓGeₓ layer. It preferably contains a colloidal dispersion of silica in water (silica sol), having a monomodal size distribution of solid particles and an average solid particle size of from 5 to 70 nm. Suitable examples are polishing agent components marketed under the names Levasil® and Glanzox. Furthermore, a solids content of from 0.25 to 20 wt. % in the polishing agent is likewise preferred. The pH of the polishing agent is preferably from 9 to 11.5.

The polishing agent may contain one or more further additives, for example abrasive additives, surface-active additives (wetting agents, surfactants), stabilizers (protective colloids), preservatives, organostatics, alcohols and/or sequestrants.

It is furthermore preferable that during polishing, the polishing pressure lies in a range of from 7 to 70 kPa and the semiconductor wafer is moved on a cycloid (hypocycloid or epicycloid) path curve, in which case a radial movement of the semiconductor wafer may also be superimposed on this movement.

According to a particularly preferred embodiment of the method according to the invention, a polishing tun comprises only one polishing step, during which one or more semiconductor wafers with a relaxed Si₁₋ₓGeₓ layer are polished on a polishing plate.

According to another particularly preferred embodiment of the method according to the invention, a polishing run comprises at least two polishing steps, in particular a material removal step and a smoothing step. The material removal and smoothing steps in this case differ essentially in that different polishing agent compositions are used. The abrasive step is selected so as to achieve a high material removal rate and a good longwave smoothing action, which sets the global planarity of the semiconductor wafer, and the second smoothing step is selected so as to achieve the least possible roughness of the resulting surface. The two substeps are preferably carried out on two different polishing plates, in order to avoid cross-contamination of the polishing agents. In the second polishing step, the polishing agent may contain the oxidant in a lower concentration, or the oxidant i.e. the component that dissolves germanium may even be omitted from the polishing agent. The smoothing step is intended to achieve comparatively little material removal with a comparatively low removal rate, for which reason the problems due to germanium particles are of secondary importance.

The polishing agent, which fills the gap between the semiconductor wafer and the polishing cloth surface, may exert strong capillary forces on the semiconductor wafer, which prevent controlled, uniform and consistently reproducible lifting of the semiconductor wafer after the end of the last polishing step. The way in which the polishing agent film breaks when lifting off will be determined by the composition of the polishing agent and the properties of the polishing agent and the polishing cloth. It has been found that irregularly distributed and concentrated polishing agent spots left behind on the semiconductor wafer after it is lifted off, particularly in the case of polishing agents with a high pH, lead to damage of the semiconductor wafer surface which has just been polished. It is consequently expedient, and therefore likewise preferred, to conclude a polishing run by gradually replacing the polishing agent with water, or with a polishing agent which allows low-residue lifting of the semiconductor wafer off from the polishing plate.

In particular devices which are used for the chemical-mechanical polishing of semiconductor substrate wafers, for chemical-mechanical planarization of the interlayers of multilevel microelectronic components or for planarizing micro-electromechanical components (MEMS), are suitable for carrying out the method according to the invention. These typically comprise one or more polishing plates and one or more polishing heads, which respectively carry one or more semiconductor wafers. The polishing heads guide the semiconductor wafers in rotation over the rotating polishing plates, which are covered with polishing cloths. Polishing agent is in this case supplied to the working gap between the semiconductor wafer and the polishing cloth surface. During polishing, the semiconductor wafers are guided by the polishing heads on the backside by means of vacuum, adherence, adhesive bonding (cement polishing) or on an air or water cushion, and optionally they are loosely held laterally by a “retainer ring”. The retainer ring may be mobile and pressed independently against the polishing cloth.

The surfaces of the polishing heads, which hold the semiconductor wafer, may be configured rigidly (cement polishing) or coated with a so-called “backing pad”, or they may consist of a membrane to which pressure is applied on the backside. If the backing pad consists of an air or water cushion, this may be subdivided into a plurality of segments that can be driven individually in terms of pressure and volume flow rate. Polishing heads with a multiplicity of individual segments, movable for example by means of piezo actuators, may also be used.

FIG. 6 shows, by way of example, a device which has a polishing head, and which is suitable for carrying out the method according to the invention, in a schematic representation. It comprises a polishing plate 17 with a polishing cloth 18 lying thereon. The polishing head 19, and a retainer ring 20 fastened to its lower end, hold a semiconductor wafer 21 during a polishing step on a predetermined path curve, which is determined essentially by the movements of the polishing plate and the polishing head. The polishing plate and the polishing head execute rotational movements about the rotation axes 22 and 26, in the rotation directions 25 and 23. In addition to the rotational movements, the polishing head may also execute a radially directed oscillating movement 24. The semiconductor wafer's backside, facing away from the polishing cloth, is exposed to pressure using an air cushion, an inner pressure zone 28 and an outer pressure zone 27 being created which are fed with compressed air through bores in the baseplate of the polishing head.

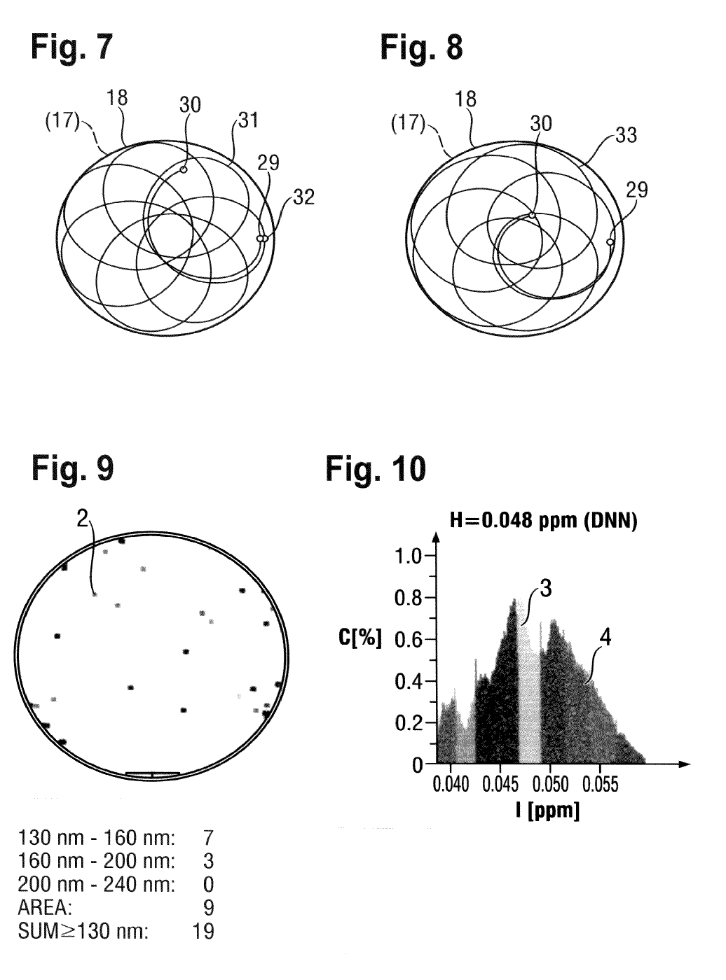

FIG. 7 shows the calculated path curve 31, which is traveled by a reference point on the edge of the semiconductor wafer over the polishing plate 17 with the polishing cloth 18 for the kinematic parameters specified in Table 1. 6 seconds elapse between the start point 29 and the end point 30 in the example shown. Because the rotation senses of the polishing head 23 and the polishing plate 25 are the same, and owing to the parameters selected, lengthened hypocycloids are obtained with characteristic loops directed outward. Shortened or lengthened hypocycloids are also referred to as hypotrochoids. The radial oscillation movement of the polishing head is manifested in the alternating amplitude of these loops and, for example, also in that the point 32 closest to the start point 29 of the path curve 31 is displaced radially relative to the former after a revolution.

TABLE 1

| | (FIG. 7) | (FIG. 8) |
|---|---|---|
| Ø semiconductor wafer | 0.3 m | |
| Ø polishing cloth | 0.8 m | |
| Ø polishing cloth revolution subcycle | 0.4 m | |
| Radial oscillation amplitude | 0.05 m | |
| Radial oscillation frequency | 5/min | |
| Polishing plate rotation speed | +67 RPM | |
| Total duration | 6 s | |
| Polishing head rotation speed | +11 RPM | −11 RPM |
| Average path speed | 1.634 m/s | 1.628 m/s |
| Path speed variation | ±0.158 m/s | ±0.167 m/s |
| Length of path curve | 9.807 m | 9.769 m |

FIG. 8 shows the path curve 33 which results when the rotation direction of the polishing head 23 is reversed and the other kinematic conditions are maintained. An epicycloid path curve 33 is obtained (lengthened epicycloids, epitrochoids) with characteristic loops directed inward. For the average path speed, its variation when travelling along the path curve and the length of the path curves traveled, different values are obtained with hypo- and epitrochoids.

Polishing cloths which are particularly suitable for carrying out the method according to the invention consist of a porous polyurethane foam. They are preferably constructed in one or several levels, in which case the thickness, hardness, number and order of the layers determine the point and surface elasticity, take-up and release of polishing agent, and many other properties. Fiber additives to the cloth's top layer, which comes in contact with the surface of the semiconductor wafer during processing, affect the material removal behavior and the surface quality obtained. It is particularly preferable to use the polishing cloth of the SPM 3100 type from Rohm & Haas Electronic Materials, CMP technologies.

The invention also relates to a semiconductor wafer, comprising a substrate layer of monocrystalline silicon as the bottom layer and a relaxed Si₁₋ₓGeₓ layer as the top layer, the top layer forming a base for the deposition of strained silicon, wherein the Si₁₋ₓGeₓ layer has the following parameters:

an AFM roughness which is less than 0.7 Å RMS, in relation to a measurement grid with an area of 10 μm×10 μm; and

a Chapman roughness which is less than 3 Å, in relation to an 80 μm filter.

Chapman Instruments is a manufacturer of standard measuring instruments for determining the roughness of ultrasmooth surfaces. The MP2000 measuring instrument is a reflection interferometer with a common beam path for the incoming and outgoing test light beam, which is guided parallel to the surface to be analyzed (“scan”). The length of the scan determines the greatest lateral correlation length contributing to the roughness value (filter). The roughness value given is determined by Fourier transformation of the phase contrast measured between the incident and reflected sub-beams.

The germanium component x of the Si₁₋ₓGeₓ layer preferably lies in a range of from x=0.10 to x=0.30. In relation to a 30 μm filter, the Chapman roughness is preferably less than 0.8 Å.

The Chapman roughness in relation to a 250 μm filter is preferably less than 5 Å. Further preferred parameters of the relaxed Si₁₋ₓGeₓ layer are a DNN haze which is less than 0.07 ppm and fewer than 12 of LPD defects in the DCN channel with size classes≧0.13 μm, in relation to a wafer surface with a diameter of 300 mm. The difference AGBIR between the global planarities of the Si₁₋ₓGeₓ layer and the substrate layer is preferably less than 0.2 μm.

The invention will be further explained below with reference to two exemplary embodiments. A multiplicity of silicon semiconductor wafers with a relaxed Si_{0.8}Ge_{0.2} layer and a diameter of 300 mm were polished on one side, in order to smooth the layer. A machine of the nHance 6EG CMP type from Strasbaugh, Inc. was used in the exemplary embodiments. Further tests were carried out on a machine of the Reflection type from Applied Materials, Inc. After the polishing, the semiconductor wafers were cleaned and dried, and the polished surfaces were studied.

The polishing device from Strasbaugh, Inc. has a polishing plate with a polishing cloth and a polishing head, which processes a semiconductor wafer fully automatically. The polishing head is universally mounted and comprises a solid baseplate, which is coated with a “backing pad”, and a mobile retainer ring. Air cushions, on which the semiconductor wafer floats during the polishing, can be set up in two concentric pressure zones, one inner and one outer, through bores in the baseplate. Pressure can be applied to the mobile retainer ring by means of a compressed air bladder, so as to pretension the polishing cloth and keep it flat upon contact with the semiconductor wafer.

The polishing device from Applied Materials, Inc. has three polishing plates which can carry different polishing cloths, and it comprises a turret which carries a plurality of polishing heads in a fixed mutual arrangement, each of which receives one semiconductor wafer. The semiconductor wafers can be moved forward synchronously from one polishing plate to the next, and they are respectively processed in succession on one of the three polishing plates.

In the first exemplary embodiment a polishing run comprised one polishing step, at the end of which a polished semiconductor wafer was respectively obtained.

An aqueous composition with a pH of 10.4, and with hydrogen peroxide in a concentration of 0.178 wt. % as the component that dissolves germanium, was used as the polishing agent. The polishing cloth was treated with the polishing agent during the polishing. Further details regarding the polishing agent and parameters of the polishing are collated in Table 2:

TABLE 2

| Parameter | Value | Unit |
|---|---|---|
| Polishing time | 230 | sec |
| Polishing pressure | 4.25 | psi (29.3 kPa) |
| Retainer ring pressure | 2.25 | psi (15.51 kPa) |
| Head speed | 60 | rpm |
| Plate speed | 70 | rpm |
| Pressure in the inner zone | 2 | psi (13.79 kPa) |
| Pressure in the outer zone | 6 | psi (41.37 kPa) |
| Polishing agent flow rate | 530 | ml/min |
| Levasil ® 200 *) | 3.44 | wt. % |
| K₂CO₃ | 0.2 | wt. % |
| H₂O₂ | 0.178 | wt. % |
| pH | 10.4 | |

*) Solids content in the polishing agent

In the second exemplary embodiment a polishing run comprised two polishing steps, namely a material removal step and a smoothing step, which were carried out with different polishing agents. The same polishing agent was used in the material removal step as in the first exemplary embodiment, except for the concentration of the hydrogen peroxide contained in it. This was 0.355 wt. %. A polishing agent to which no oxidant had been added was used in the smoothing step. Further details regarding the polishing agent and parameters of the smoothing step are collated in Table 3:

TABLE 3

| Parameter | Value | Unit |
|---|---|---|
| Polishing time | 80 | sec |
| Polishing pressure | 3 | psi (20.68 kPa) |
| Retainer ring pressure | 1.5 | psi (10.34 kPa) |
| Head speed | 10 | rpm |
| Plate speed | 70 | rpm |
| Pressure in the inner zone | 6 | psi (41.37 kPa) |
| Pressure in the outer zone | 2 | psi (13.79 kPa) |
| Polishing agent flow rate | 400 | ml/min |
| Glanzox 3900 *) | 1 | wt. % |
| pH | 10.4 | |

*) Solids content in the polishing agent

FIG. 9 and FIG. 10 show the results of scattered light measurements on polishing of a relaxed Si_{0.8}Ge_{0.2} layer, carried out according to the second exemplary embodiment. In the DCN channel, 7 LPD defects are counted for an LSE size of 0.13 μm-0.16 μm, 3 are counted for 0.16 μm-0.20 μm, none are counted for 0.20 μm-0.24 μm and 9 are counted for “area counts” (≧0.24 μm). Thus, in total for the LPD defects≧0.13 μm, 7+3+0+9=19. (The representation of the defect distribution over the surface in FIG. 9 reflects all measured LPD defects, i.e. even those ≦0.13 μm.) The DNN haze spectrum in FIG. 10 comprises only number frequencies C at very low scattering intensities I (cf. FIG. 3) and decreases almost monotonically toward higher intensities. (The low intensity region 3 and high-intensity region 4 merge substantially homogeneously with one another.) The DNN haze integrated over all intensities I and weighted with the number frequency C over the semiconductor surface contains only 0.048 ppm of the scattering intensity of the incident measurement beam.

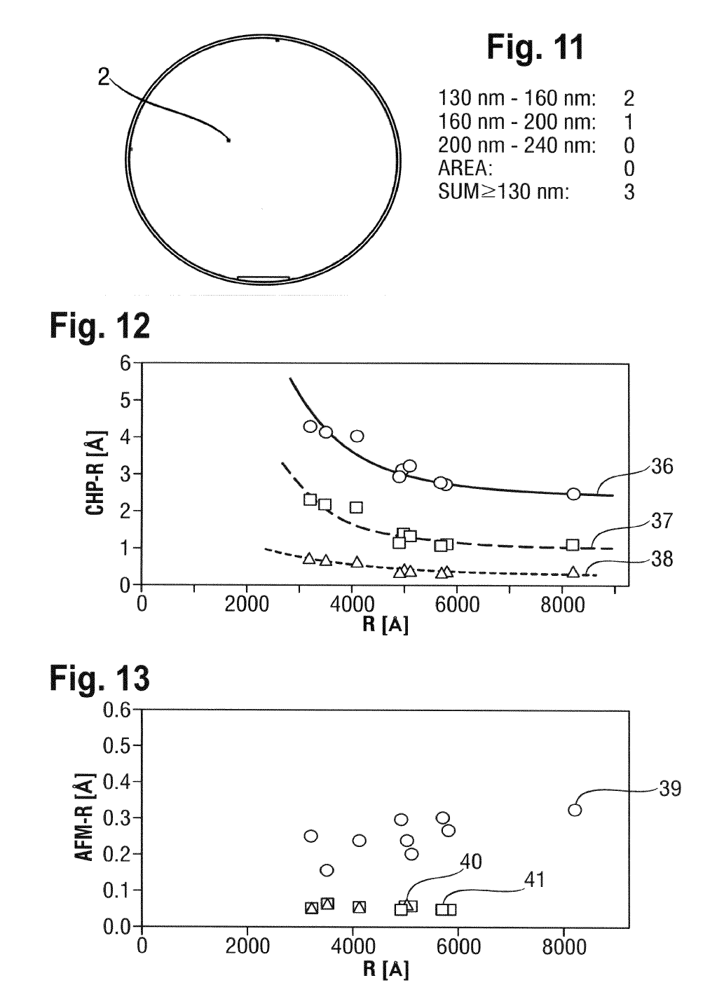

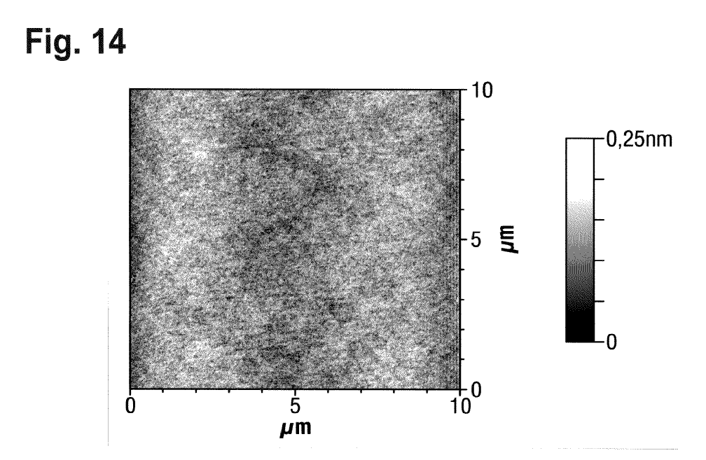

The scattered light measurements were carried out immediately after polishing the relaxed Si_{0.8}Ge_{0.2} layer and after removing the polishing agent residue. In order to remove loosely adhering particles, which vitiate the polishing result, the polished semiconductor wafer was cleaned. Only 3 LPD defects with an LSE size≧0.13 μm were subsequently counted in the DCN channel (FIG. 11).

When polishing the relaxed Si₁₋ₓGeₓ layer, it was found that minimal material removal is necessary in order to obtain a smooth surface. This applies in particular for roughnesses with longer correlation lengths. FIG. 12 shows RMS Chapman roughnesses at a correlation length of 250 μm (36), 80 μm (37) and 30 micrometer (38). For very long correlation lengths (36), the roughness still decreases somewhat more with increasing material removal even in excess of 5000 Å, while no further smoothing is achieved beyond material removal of 5000 Å at short correlation lengths (37 and in particular 38). For very short correlation lengths, essentially no decrease in the roughness is to be observed with increasing material removal. Thus all values calculated for the RMS roughness from 40 μm×40 μm (39), 10 μm×10 μm (40) and 1 m×1 μm (41) AFM measurements are already constant after the smallest polishing material removal carried out, namely 3000 Å (FIG. 13). The inventors explain this in that short-wave irregularities are initially eroded preferentially owing to the elasticity of the polishing cloth, and then longer-wave irregularities are gradually eliminated only with increasing material removal.

Since the planarity even at longer correlation lengths is crucial for suitability of the polished relaxed Si₁₋ₓGeₓ layer for the structuring of particularly demanding components, material removal of at least 3500 Å (350 nm) is preferred when carrying out the method according to the invention.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A method for the single-sided polishing of semiconductor wafers which are provided with a relaxed Si₁₋ₓGeₓ layer, comprising:
the polishing of a multiplicity of semiconductor wafers in a plurality of polishing runs, a polishing run comprising at least one polishing step and at least one of the multiplicity of semiconductor wafers being obtained with a polished Si₁₋ₓGeₓ layer at the end of each polishing run; and
moving the at least one semiconductor wafer during the at least one polishing step over a rotating polishing plate provided with a polishing cloth while applying polishing pressure, and supplying polishing agent between the polishing cloth and the at least one semiconductor wafer, a polishing agent being supplied which contains an alkaline component and a component that dissolves germanium.

2. The method of claim 1, wherein the component that dissolves germanium comprises at least one oxidant.

3. The method of claim 2, wherein the polishing agent contains the oxidant in a concentration of from 0.01 mol/kg to 1.0 mol/kg.

4. The method of claim 1, wherein a component that dissolves germanium comprises hydrogen peroxide, ozone, sodium hypochlorit or a mixture thereof.

5. The method of claim 1, wherein the alkaline component comprises potassium carbonate (K₂CO₃), potassium hydroxide (KOH), sodium hydroxide (NaOH), ammonium hydroxide (NH₄OH), tetramethylammonium hydroxide (N(CH₃)₄OH), or a mixture thereof.

6. The method of claim 1, wherein the polishing agent comprises silica sol having a monomodal size distribution of solid particles and an average solid particle size of from 5 to 70 nm.

7. The method of claim 1, wherein material removal of at least 350 nm is achieved in the course of the polishing run.

8. The method of claim 1, wherein a material removal polishing step with a removal rate of at least 1.5 nm/s is carried out as the at least one polishing step.

9. The method of claim 1, wherein the polishing agent contains a solids content of from 0.25 to 20 wt. %.

10. The method of claim 1, wherein the polishing agent has a pH of from 9 to 11.5.

11. The method of claim 1, wherein the polishing pressure is from 7 to 70 kPa.

12. The method of claim 1, wherein the at least one semiconductor wafer is moved on a cycloid path curve.

13. The method of claim 12, wherein the at least one semiconductor wafer is also moved radially in oscillation.

14. The method of claim 1, wherein the polishing cloth is conditioned with a cleaning agent during or after a polishing step or after a number of polishing runs.

15. The method of claim 14, wherein the cleaning agent contains the germanium-dissolving component in a concentration of from 0.01 mol/kg to 1.5 mol/kg.

16. The method of claim 1, wherein the polishing run comprises at least two polishing steps on at least two different polishing plates.

17. A semiconductor wafer, comprising a substrate layer of monocrystalline silicon as the bottom layer and a relaxed Si₁₋ₓGeₓ layer as the top layer, the top layer forming a base for the deposition of strained silicon, wherein the Si₁₋ₓGeₓ layer comprises the following parameters:
an AFM roughness which is less than 0.7 Å RMS, in relation to a measurement grid with an area of 10 μm×10 μm; and
a Chapman roughness which is less than 3 Å, in relation to a 80 μm filter.

18. The semiconductor wafer of claim 17, wherein the Chapman roughness is less than 0.8 Å, in relation to a 30 μm filter.

19. The semiconductor wafer of claim 17, wherein the Chapman roughness is less than 5 Å, in relation to a 250 μm filter.

20. The semiconductor wafer of claim 17, wherein the difference AGBIR between the global flatness of the Si₁₋ₓGeₓ layer and the substrate layer is less than 0.2 μm.

21. The semiconductor wafer of claim 17, wherein the Si₁₋ₓGeₓ layer comprises the following further parameter:
a DNN haze which is less than 0.07 ppm.

22. The semiconductor wafer of claims 17, wherein the Si₁₋ₓGeₓ layer comprises the following further parameter:
less than 12 of LPD defects in the DCN channel with sizes greater than or equal to 0.13 μm, in relation to a wafer surface with a diameter of 300 mm.
